(19) United States
(12) Patent Application Publication
(10) Pub. No.: US 2025/0095766 A1
(43) Pub. Date: Mar. 20, 2025

(54) MEMORY CONTROLLER, MEMORY SYSTEM AND OPERATION METHOD THEREOF

(71) Applicant: Yangtze Memory Technologies Co., Ltd., Wuhan (CN)

(72) Inventor: Teng ZHOU, Wuhan (CN)

(21) Appl. No.: 18/438,208

(22) Filed: Feb. 9, 2024

(30) Foreign Application Priority Data
Sep. 19, 2023 (CN) 202311213384.0

(51) Int. Cl. G11C 29/52; G11C 16/26; G11C 29/02

(52) U.S. Cl. CPC G11C 29/52; G11C 16/26; G11C 29/028

(57) ABSTRACT

Examples of the present application disclose a memory controller, a memory system and an operation method thereof. The operation method includes: determining that a memory device is in a first use state in response to determining that a read error is occurred in the memory device of the memory system; determining a first voltage offset corresponding to the first use state according to a preset mapping relationship that includes a corresponding relationship between a use state of the memory device and a voltage offset, the voltage offset including an offset value relative to a preset reference read voltage; and obtaining at least one first read voltage for performing a read operation on the memory device in the first use state according to the preset reference read voltage and the first voltage offset.

### CROSS-REFERENCE TO RELATED APPLICATIONS

This application claims the benefit of priority to Chinese Patent Application No. 202311213384.0, filed on Sep. 19, 2023, the disclosure of which is hereby incorporated by reference in its entirety.

### TECHNICAL FIELD

The present application relates to the technical field of memories, and particularly to a memory controller, a memory system and an operation method thereof.

### BACKGROUND

With the development of memory technology, a 3D NAND Flash develops from a single level cell (SLC) capable of storing 1 bit of information and a double level cell (DLC) capable of storing 2 bits of information to a triple level cell capable of storing 3 bits of information and even a quadruple level cell capable of storing 4 bits of information. For a memory device with increasingly more layers and stored bits, there is a need to optimize the performance of the memory device.

### SUMMARY

In view of this, examples of the present application provide a memory controller, a memory system and an operation method thereof.

In a first aspect, examples of the present application provide an operation method of a memory system, comprising:
determining that a memory device is currently in a first use state in response to determining that a read error is occurred in the memory device of the memory system;
determining a first voltage offset corresponding to the first use state according to a preset mapping relationship, wherein the preset mapping relationship comprises a corresponding relationship between a use state of the memory device and a voltage offset, and the voltage offset includes an offset value relative to a preset reference read voltage; and
obtaining at least one first read voltage used for performing a read operation on the memory device in the first use state according to the preset reference read voltage and the first voltage offset.

In the above solution, the first voltage offset includes one or more first voltage offset values; the at least one first read voltage includes one or more first read voltages; and the operation method further comprises:
selecting at least one of the one or more first read voltages as a soft read reference voltage of soft decoding;
for each soft read reference voltage, obtaining a corresponding set of soft read voltages including the soft read reference voltage according to the soft read reference voltage and a preset offset rule; and
performing the soft decoding on the memory device according to at least one set of soft read voltages.

In the above solution, the preset mapping relationship comprises a mapping table; and the operation method further comprises:
putting the memory device in different use states;
obtaining a Read Retry Table (RRT) from the memory device in each use state; traversing the RRT, performing a read operation on the memory device one by one, and obtaining at least one voltage offset in the corresponding RRT when a read error meets a preset condition; and establishing a corresponding relationship between each of the use states and the corresponding at least one voltage offset; and
generating the mapping table according to each corresponding relationship.

In the above solution, state parameters comprise at least one of: an erase count, a program count, a read count, a read temperature, a program temperature and a program to read time interval of the memory device; and
the putting the memory device in different use states comprises:
assigning values to the erase count, the program count, the read count, the read temperature, the program temperature and the program to read time interval to form multiple sets of state parameters; and
processing the memory device according to the multiple sets of state parameters to put the memory device in different use states,
wherein each set of state parameters corresponds to one use state of the memory device.

In the above solution, the determining the first voltage offset corresponding to the first use state according to the preset mapping relationship comprises:
comparing the first use state with each second use state recorded in the mapping table; and
obtaining the first voltage offset from the mapping table according to a comparison result.

In the above solution, the state parameters include a plurality of state parameters; the comparing the first use state with the second use state recorded in the mapping table comprises:
comparing each parameter of the state parameters in the first use state with each parameter of the state parameters in each second use state correspondingly; and
the obtaining the first voltage offset from the mapping table according to the comparison result comprises:
determining a second voltage offset corresponding to the second use state from the mapping table as the first voltage offset, if the comparison result comprises that a ratio of the state parameters of the first use state and a certain second use state having the same parameter exceeds a first set threshold value; or
determining a second voltage offset corresponding to the second use state from the mapping table as the first voltage offset, if the comparison result comprises that an absolute value of a difference in corresponding parameters in the state parameters of the first use state and a certain second use state does not exceed a second set threshold value; or
determining a second voltage offset corresponding to the second use state from the mapping table as the first voltage offset, if the comparison result comprises that a ratio of the state parameters of the first use state and a certain second use state having the same parameter exceeds the first set threshold value and an absolute value of a difference in corresponding parameters in the state parameters of the first use state and the second use state does not exceed the second set threshold value.

In the above solution, the method further comprises:
updating the erase count, the program count, the read count, the read temperature, the program temperature and the program to read time interval regularly; and
the determining that the memory device is currently in the first use state comprises:
looking up the erase count, the program count, the read count, the read temperature, the program temperature and the program to read time interval updated latest as the first use state.

In the above solution, the method further comprises:
determining a set of hard read voltages according to the preset reference read voltage and a Read Retry Table (RRT) before determining that the memory device is currently in the first use state, wherein the set of hard read voltages comprises a default read voltage and a plurality of re-read voltages, and the plurality of re-read voltages have a certain offset from the preset reference read voltage; and
performing hard decoding on the memory device according to the set of hard read voltages.

In the above solution, the performing the soft decoding on the memory device according to at least one set of soft read voltages comprises:
performing the soft decoding on the memory device gradually according to one set of soft read voltages of a plurality of sets of soft read voltages; and finishing the soft decoding on the memory device until the soft decoding passes and/or the number of times of performing the soft decoding reaches a preset threshold value.

In the above solution, the performing the soft decoding on the memory device according to one set of soft read voltages comprises:
obtaining a set of voltage offsets corresponding to the set of soft read voltages;
configuring the set of voltage offsets to the memory device to make the memory device obtain the set of soft read voltages according to the set of voltage offsets and the preset reference read voltage, and obtain a set of soft read data according to the set of soft read voltages; and
performing soft decoding on the set of soft read data.

In a second aspect, examples of the present application further provide a memory controller coupled with one or more memory devices and comprising a processor, wherein
the processor is configured to: determine that the memory device is in a first use state in response to determining that a read error is occurred in the memory device; determine a first voltage offset corresponding to the first use state according to a preset mapping relationship; and obtain at least one first read voltage used for performing a read operation on the memory device in the first use state according to the preset reference read voltage and the first voltage offset, wherein the preset mapping relationship includes a corresponding relationship between a use state of the memory device and a voltage offset, and the voltage offset includes an offset value relative to a preset reference read voltage.

In the above solution, the memory controller further comprises a memory; and
the processor is further configured to: send a first read command to the memory device; receive the preset mapping relationship fed back by the memory device in response to the first read command; and buffer the preset mapping relationship to the memory.

In the above solution, the first voltage offset includes one or more first voltage offset values; the at least one first read voltage includes one or more first read voltages; and the processor is further configured to: select at least one first read voltage as a soft read reference voltage of soft decoding; obtain a corresponding set of soft read voltages including the soft read reference voltage according to each soft read reference voltage and a preset offset rule; and perform the soft decoding on the memory device according to at least one set of soft read voltages.

In the above solution, the preset mapping relationship comprises a mapping table; the memory controller further comprises a memory; and
the processor is further configured to: send a second read command to the memory device; receive a Read Retry Table (RRT) fed back by the memory device in response to the second read command, and buffer the RRT to the memory; put the memory device in different use states; in each use state, traverse the RRT in the memory, perform a read operation on the memory device one by one, and obtain at least one voltage offset in the corresponding RRT when a read error meets a preset condition; establish a corresponding relationship between each of the use states and the corresponding at least one voltage offset; and generate the mapping table according to each corresponding relationship.

In the above solution, wherein state parameters comprise at least one of: an erase count, a program count, a read count, a read temperature, a program temperature and a program to read time interval of the memory device; and the processor is further configured to: assign values to the erase count, the program count, the read count, the read temperature, the program temperature and the program to read time interval to form multiple sets of state parameters; and process the memory device according to the multiple sets of state parameters to put the memory device in different use states, wherein each set of state parameters corresponds to one use state of the memory device.

In the above solution, the processor is further configured to: compare the first use state with each second use state recorded in the mapping table; and obtain the first voltage offset from the mapping table according to a comparison result.

In the above solution, the processor is further configured to: compare each parameter of the state parameters in the first use state with each parameter of the state parameters in each second use state correspondingly,
wherein a second voltage offset corresponding to the second use state is determined from the mapping table as the first voltage offset, if the comparison result comprises that a ratio of the state parameters of the first use state and a certain second use state having the same parameter exceeds a first set threshold value; or a second voltage offset corresponding to the second use state is determined from the mapping table as the first voltage offset, if the comparison result comprises that an absolute value of a difference in corresponding parameters in the state parameters of the first use state and a certain second use state does not exceed a second set threshold value; or a second voltage offset corresponding to the second use state is determined from the mapping table as the first voltage offset, if the comparison result comprises that a ratio of the state parameters of the first use state and a certain second use state having the same parameter exceeds the first set threshold value and an absolute value of a difference in corresponding parameters in the state parameters of the first use state and the second use state does not exceed the second set threshold value.

In the above solution, the processor is further configured to: update the erase count, the program count, the read count, the read temperature, the program temperature and the program to read time interval in the memory regularly; and look up the erase count, the program count, the read count, the read temperature, the program temperature and the program to read time interval updated latest from the memory as the first use state.

In a third aspect, examples of the present application further provide a memory system, comprising:
one or more memory devices; and
a memory controller coupled with the one or more memory devices and configured to control the one or more memory devices, wherein
the memory controller comprises a processor configured to: determine that a memory device is in a first use state in response to determining that a read error is occurred in the memory device; determine a first voltage offset corresponding to the first use state according to a preset mapping relationship; and obtain at least one first read voltage used for performing a read operation on the memory device in the first use state according to the preset reference read voltage and the first voltage offset,
wherein the preset mapping relationship includes a corresponding relationship between a use state of the memory device and a voltage offset, and the voltage offset includes an offset value relative to a preset reference read voltage.

In the above solution, the memory device comprises: a memory array and a peripheral circuit coupled with the memory array, wherein
the peripheral circuit comprises a control logic and a register, wherein
the processor is further configured to: obtain a set of voltage offsets corresponding to one set of soft read voltages of a plurality of sets of soft read voltages; and configure each voltage offset of the set of voltage offsets to the register;
the control logic is configured to: access the register to obtain the set of voltage offsets; obtain the set of soft read voltages according to a preset reference read voltage and the set of voltage offsets; and gradually provide each soft read voltage of the set of soft read voltages to selected word lines corresponding to selected memory cells included in the memory array to obtain a corresponding set of soft read data; and
the processor is further configured to: perform soft decoding on the set of soft read data.

Examples of the present application provide a memory controller, a memory system and an operation method thereof. The operation method comprises: determining that a memory device is currently in a first use state in response to that a read error is occurred in the memory device of the memory system; determining a first voltage offset corresponding to the first use state according to a preset mapping relationship, wherein the preset mapping relationship includes a corresponding relationship between a use state of the memory device and a voltage offset, and the voltage offset is an offset value relative to a preset reference read voltage; and obtaining a first read voltage used for performing a read operation on the memory device in the first use state according to the preset reference read voltage and the first voltage offset. The operation method provided by the examples of the present application determines the first voltage offset corresponding to the first use state of the memory device according to the preset mapping relationship, and then obtains the first read voltage required to read the memory device according to the first voltage offset and the preset reference read voltage. This method of obtaining the suitable read voltage may be applied to various kinds of memory systems, such as a memory system including a memory controller without complex operation capability, a memory system with a memory device not having a function of searching a suitable read voltage, etc. Even the memory system including the memory controller with complex operation capability and/or the memory system with the memory device having the function of searching a suitable read voltage may also employ the operation method provided by the examples of the present application to determine the required read voltage, because it is simple in operation (such as, the voltage offset can be obtained by using a simple match lookup operation), and can quickly obtain the read voltage matched with a practical application scenario.

### BRIEF DESCRIPTION OF THE DRAWINGS

In the drawings not necessarily drawn to scale, like labels may describe similar components in different views. Like numerals having different letter suffixes may represent different examples of similar components. The drawings illustrate generally, by way of example, but not by way of limitation, various examples discussed in the present document.

FIG. 1 is a schematic diagram of an example system having a memory system provided by an example of the present application;

FIG. 2a is a schematic diagram of an example memory card having a memory system provided by an example of the present application;

FIG. 2b is a schematic diagram of an example solid-state drive having a memory system provided by an example of the present application;

FIG. 3 is a schematic structural diagram of a memory controller provided by an example of the present application;

FIG. 4 is a schematic structure diagram of a memory device provided by an example of the present application;

FIG. 5 is a schematic diagram of an example memory device comprising a memory array and a peripheral circuit provided by an example of the present application;

FIG. 6 is an example schematic diagram of soft decoding provided by an example of the present application;

FIG. 7 is a flow diagram I of an operation method of a memory system provided by an example of the present application;

FIG. 8 is a flow diagram II of an operation method of a memory system provided by an example of the present application;

FIG. 9 is a flow diagram III of an operation method of a memory system provided by an example of the present application;

FIG. 10 is a flow diagram IV of an operation method of a memory system provided by an example of the present application;

FIG. 11 is an example schematic diagram of a set of soft read voltages provided by an example of the present application;

FIG. 12 is a flow diagram V of an operation method of a memory system provided by an example of the present application; and

FIG. 13 is a schematic structural diagram of a memory controller provided by an example of the present application.

### DETAILED DESCRIPTION

Examples disclosed by the present application will be described below in detail with reference to the figures. Although the examples of the present application are shown in the figures, it is to be understood that, the present application may be implemented by any form without being limited by the specific implementations as set forth herein. Rather, these examples are provided in order for understanding the present application more thoroughly, and can fully convey the scope disclosed by the present application to those skilled in the art.

In the description below, many specific details are presented to provide a more thorough understanding of the present application. However, it is apparent to those skilled in the art that the present application may be carried out without one or more of these details. In other examples, in order to avoid confusing with the present application, some technical features well-known in the art are not described; that is, not all features of actual examples are described herein, and well-known functions and structures are not described in detail.

In the drawings, sizes and relative sizes of layers, areas and elements may be exaggerated for clarity. Like reference numerals denote like elements throughout the specification.

It should be understood that when an element or a layer is referred to as being “on”, “adjacent to”, “connected to”, or “coupled to” other elements or layers, it may be directly on, adjacent to, connected to, or coupled to the other elements or layers, or one or more intervening elements or layers may be present. In contrast, when an element is referred to as being “directly on”, “immediately adjacent to”, “directly connected to”, or “directly coupled to” other elements or layers, no intervening elements or layers are present. It should be understood that, although the terms first, second, third, etc., may be used to describe various elements, components, areas, layers and/or portions, these elements, components, areas, layers and/or portions should not be limited by these terms. These terms are only used to distinguish one element, component, area, layer or portion from another element, component, area, layer or portion. Thus, a first element, component, area, layer or portion discussed below may be represented as a second element, component, area, layer or portion, without departing from the teachings of the present application. When the second element, component, area, layer or portion is discussed, it does not mean that the first element, component, area, layer or portion is necessarily present in the present application.

The spatially relative terms, such as “beneath”, “below”, “lower”, “under”, “over”, “upper”, and the like, may be used herein for ease of description to describe one element or feature's relationship to other elements or features as illustrated in the figures. It should be understood that, the spatially relative terms are intended to further encompass different orientations of a device in use or operation in addition to the orientation depicted in the figures. For example, if a device in the drawings is turned over, then an element or a feature described as “below other elements”, or “under other elements”, or “beneath other elements” will be orientated to be “above” the other elements or features. Thus, the example terms, “below” and “beneath”, may comprise both upper and lower orientations. The device may be orientated otherwise (rotated by 90 degrees or other orientations), and the spatially descriptive terms used herein are interpreted accordingly.

The terms used herein are only intended to describe the specific examples, and are not used as limitations of the present application. As used herein, unless otherwise indicated expressly in the context, “a”, “one” and “the” in a singular form are also intended to include a plural form. It should also be understood that the terms “consist of” and/or “comprise”, when used in this specification, determine the presence of a feature, integer, step, operation, element and/or component, but do not preclude the presence or addition of one or more of other features, integers, steps, operations, elements, components, and/or groups. As used herein, the term “and/or” includes any or all combinations of the listed relevant items.

In order to be capable of understanding the characteristics and the technical contents of the examples of the present application in more detail, implementation of the examples of the present application is set forth in detail below in conjunction with the drawings, and the drawings are only used for reference and illustration, instead of being used to limit the examples of the present application.

A memory device is a memory apparatus used to store information in modern information technologies. As a typical non-volatile memory device, a 3D NAND (Not-And) memory device has become a mainstream product in the memory market due to its relatively high storage density, controllable production costs, appropriate program and erase speeds, and a retention characteristic. With the increase of the number of stored bits and the increase of the number of stacked layers of a memory cell, types of error occurring during performing a read operation on the memory device are more and more complex.

Based on one or more of the above problems, examples of the present application provide an operation method of a memory system, which determines at least one offset voltage through a preset mapping relationship between a use state of the memory device and an offset voltage pre-stored in a memory controller, and then obtains at least one read voltage according to these voltage offsets, such that a suitable read voltage is obtained without operation of a module such as the memory controller, and the memory device is not required to have a function of searching a suitable read voltage; the read voltage matched with a practical application scenario can be obtained quickly and accurately. The read data with high accuracy is obtained by using the suitable read voltage, such that the decoding time for the read data by using a decoder will be shortened, and the read speed can be improved.

The examples of the present disclosure are further illustrated below in detail in conjunction with the drawings and particular examples.

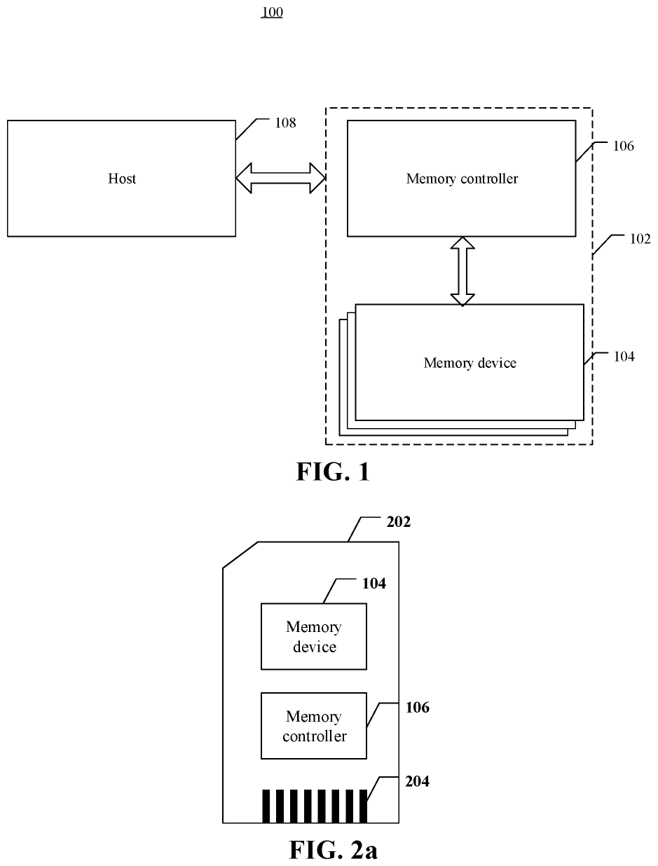

FIG. 1 is a schematic diagram of an example system having a memory system provided by an example of the present disclosure. In FIG. 1, the system 100 may be a mobile phone, a desktop computer, a laptop computer, a tablet computer, a vehicle computer, a gaming console, a printer, a positioning apparatus, a wearable electronic apparatus, a smart sensor, a Virtual Reality (VR) apparatus, an Augmented Reality (AR) apparatus, or any other suitable electronic apparatuses having memory systems therein. As shown in FIG. 1, the system 100 may comprise a host 108 and a memory system 102. The host 108 may comprise a processor, such as a central processing unit (CPU) or a system on chip (SoC), wherein the system on chip may be, for example, an application processor (AP). The host 108 further comprises at least one operating system (OS) which can usually manage and control functions and operations executed in the host 108. The OS can enable interoperation between the host 108 coupled with the memory system 102 and users who need and use the memory system 102. The OS can support functions and operations corresponding to a request of the user, such as but not limited to, depending on whether the type of the host 108 is a mobile host, the OS may be classified into a general operating system and a mobile operating system, wherein the general operating system may include a personal operating system and an enterprise operating system. The personal operating system may be an operating system including Windows and Chrome for supporting service for general purposes. The enterprise operating system may be an operating system dedicated to ensuring and supporting higher performance, including Windows server, Linux, Unix, and the like. The mobile operating system may refer to an operating system for mobile services or functions (e.g., a power saving function). In general, the mobile operating system may be an operating system such as Android, iOS, Windows Mobile and the like. In some examples, the host 108 may comprise a plurality of OSs. Correspondingly, the host 108 may run a plurality of operating systems related to the memory system 102. In some other examples, the host 108 converts the request of the user to one or more commands, and transfers the one or more commands into the memory system 102 to make the memory system 102 execute operations related to the one or more commands.

The memory system 102 can operate or perform particular functions or perform various operations inside in response to the request of the host 108. In some examples, the memory system 102 can store data accessed by the memory host 108. The memory system 102 can act as a primary memory system or a secondary memory system of the host 108. The memory system 102 and the host 108 can be electrically connected and communicate according to a corresponding protocol. The memory system 102 can be implemented and packaged in different end electronic products, including, but not limited to, a solid-state drive (SSD), a multi-media card (MMC), an embedded MMC (eMMC), a reduced size MMC (RSMMC), a micro MMC, a Secure Digital (SD) card, a mini SD, a micro SD, a Universal Serial Bus (SUB) memory apparatus, a Universal Flash Storage (UFS) apparatus, a Compact Flash (CF) card, a smart media (SM) card, and a memory stick, etc.

In some examples, the memory system 102 may be further configured as a part of the following devices: a computer, an ultra-mobile PC (UMPC), a workstation, a netbook, a personal digital assistant (PDA), a portable computer, a network tablet, a tablet computer, a wireless telephone, a mobile telephone, a smartphone, an electronic book, a portable multimedia player (PMP), a portable game player, a navigation system, a black box, a digital camera, a digital multimedia broadcasting (DMB) player, a three-dimensional (3D) television, a smart television, a digital audio recorder, a digital audio player, a digital picture recorder, a digital picture player, a digital video recorder, a digital video player, a memory device configured with a data center, a device capable of transmitting and receiving information in a wireless environment, one of various electronic devices configured with a home network, one of various electronic devices configured with a computer network, one of various electronic devices configured with a remote information processing network, a radio frequency identification (RFID) device, or one of various components configured with a computing system.

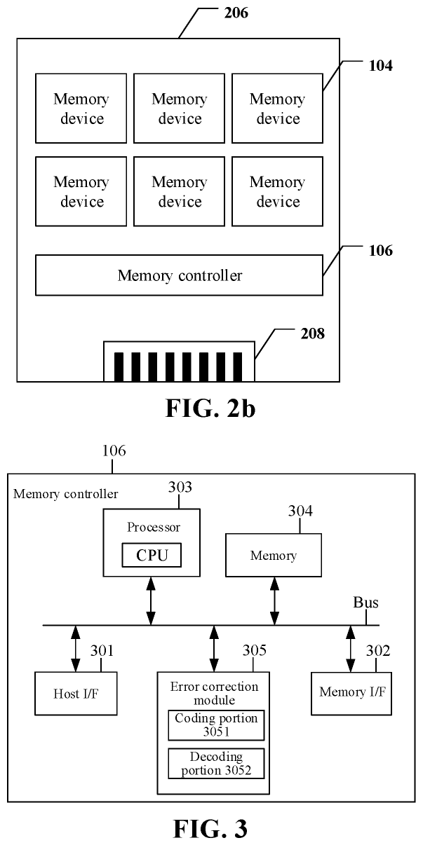

Returning to FIG. 1, the memory system 102 may comprise one or more memory devices 104 and a memory controller 106. The memory controller 106 may control the memory device 104 in response to a request of the host 108. For example, the memory controller 106 can read data from the memory device 104, transfer the read data to the host 108, and may also receive data to be stored from the host 108, and store the data to be stored to the memory device 104. That is to say, the memory controller 106 can control read (or program) operation, read operation, erase operation or background operation, etc. of the memory device 104. Moreover, the memory system 102 can be implemented and packaged into different types of electronic end products. In one example as shown in FIG. 2a, the memory controller 106 and a single memory device 104 may be integrated into a memory card 202. The memory card 202 may include a PC card (PCMCIA, Personal Computer Memory Card International Association), a CF card, a Smart Media (SM) card, a memory stick, a Multimedia card (MMC, RS-MMC, MMCmicro), an SD card (SD, miniSD, microSD, SDHC), a UFS, etc. The memory card 202 may further comprise a memory card connector 204 coupling the memory card 202 with a host (e.g., the host 108 in FIG. 1). In another example as shown in FIG. 2b, the memory controller 106, and a plurality of memory devices 104 may be integrated into an SSD 206. The SSD 206 may further include an SSD connector 208 coupling the SSD 206 with a host (e.g., the host 108 in FIG. 1). In some implementations, the storage capacity and/or the operation speed of the SSD 206 are greater than the storage capacity and/or the operation speed of the memory card 202.

As shown in FIG. 3, the memory controller 106 may comprise a host I/F (or a front-end interface) 301, a memory I/F (or a rear-end interface) 302, a processor 303 and a memory 304, wherein the above-mentioned components 301, 302, 303 and 304 in the memory controller 106 may share a transmission signal inside the memory controller 106 through an internal bus. In some examples, the host I/F 301 may interface the host 108 with the memory system 102 in response to a protocol of the host 108, and the host I/F 301 exchanges command and data transmission operations between the host 108 and the memory system 102. The host I/F 301 may process commands and data sent by the host 108, and may comprise at least one of: a Universal Serial Bus (USB), a Multi-media Card (MMC), a Peripheral Component Interconnection-Express (PCI-E or PCIe), a Small Computer System Interface (SCSI), a Serial SCSI (SAS), a Serial Advanced Technology Attachment (SATA), a Parallel Advanced Technology Attachment (PATA), a Small Computer System Interface (SCSI), Enhanced Small Disk Interface (ESDI) and Integrated Drive Electronics (IDE). In some examples, the host I/F 301 is a component of the memory system 102 for exchanging data with the host 108, and may be implemented by a firmware called a host interface layer (HIL).

The memory I/F 302 may be an interface transferring commands and data between the memory controller 106 and the memory device 104, and allows the memory controller 106 to control the memory device 104 in response to a request transferred from the host 108. The memory I/F 302 may generate a control signal used to control the memory device 104. In some examples, if the memory device 104 is a NAND flash memory, the memory I/F 302 may write data into or read data from the memory device 104 under the control of the processor 303. The memory I/F 302 may process commands and data between the memory controller 106 and the memory device 104, for example, an operation of a NAND flash interface, especially an operation between the memory controller 106 and the memory device 104. According to examples, the memory I/F 302 may be implemented as a component for exchanging data with the memory device 104 through a firmware referred to as a flash interface layer (FIL).

The processor 303 may be implemented as a microprocessor or a central processor unit (CPU). The memory system 102 may comprise one or more processors 303. The processor 303 can control all operations of the memory system 102. As an example instead of limitation, the processor 303 may control a program operation or a read operation of the memory device 104 in response to a write request or a read request from the host 108. According to the examples, the processor 303 may use or run a firmware to control all operations of the memory system 102. In the present disclosure, the firmware may be referred to as a flash translation layer (FTL). The FTL may perform an operation as an interface between the host 108 and the memory device 104. The host 108 may transfer requests related to the write operation and the read operation to the memory device 104 through the FTL. For example, when an operation requested from the host 108 is performed in the memory device 104, the memory controller 106 uses the processor 303. The processor 303 coupled with the memory device 104 may process an instruction or a command related to a command from the host 108. The memory controller 106 may perform a foreground operation such as a command operation corresponding to a command input from the host 108, for example, a program operation corresponding to a write command, a read operation corresponding to a read command, an erase/discard operation corresponding to an erase/discard command, and a parameter setting operation corresponding to a parameter setting command or a feature setting command with a setting command.

For another example, the memory controller 106 may perform background operations on the memory device 104 through the processor 303. As an example instead of limitation, these background operations may include a garbage collection (GC) operation, a wear leveling (WL) operation, a mapping clear operation and a bad block management operation for checking or searching for a bad block. The garbage collection operation may comprise an operation of copying and processing data stored in some memory block in the memory device 104 into another memory block. The wear leveling operation may comprise an operation of exchanging and processing the stored data between memory blocks of the memory device 104. The mapping clear operation may comprise an operation of storing mapping data stored in the memory controller 106 in a memory block of the memory device 104. The bad block management operation may comprise an operation of checking and processing bad blocks in the memory device 104. The memory controller 106 may respond to an operation of accessing a memory block of the memory device 104, wherein the operation of accessing the memory block of the memory device 104 may comprise a foreground operation or a background operation performed on the memory block of the memory device 104.

The memory 304 may be a working memory of the memory controller 106 and is configured to store data for driving the memory controller 106. In an example, when the memory controller 106 controls the memory device 104 in response to a request of the host 108, the memory 304 may store a firmware driven by the processor 303 and data (e.g., metadata) required for driving the firmware. The memory 304 may be also a buffer memory of the memory controller 106, and is configured to temporarily store write data transferred from the host 108 to the memory device 104 and read data transferred from the memory device 104 to the host 108. The memory 304 may comprise a program memory, a data memory, a write buffer/cache, a read buffer/cache, a data buffer/cache and a mapping buffer/cache for storing the write data and the read data. The memory 304 may be implemented as a volatile memory. The memory 304 may be implemented as a static random access memory (SRAM), a dynamic random access memory (DRAM) or both.

Although FIG. 3 shows that the memory 304 is included in the memory controller 106, the present disclosure is not limited thereto. In implementations, the memory 304 may be included outside the memory controller 106, and the memory controller 106 may input and output data to the memory 304 through a separate memory interface (not shown).

An error correction (ECC) module 305 has a coding portion 3051 and a decoding portion 3052, wherein the coding portion 3051 may perform a coding operation such as LDPC on data to be programmed into the semiconductor memory device 104, and output data including an additional parity check bit. The parity check bit may be stored in the semiconductor memory device 104. The decoding portion 3052 may perform error correction decoding on data read from the semiconductor memory device 104; may also determine whether the error correction decoding passes and output an instruction signal based on the determination result; and may also use the parity check bit generated by the LDPC coding operation to correct an error bit of the data.

Here, although FIG. 3 shows that the error correction module 305 is included in the memory controller 106, the present disclosure is not limited thereto. In implementations, the error correction module 305 may be included outside the memory controller 106, and the memory controller 106 may perform data communication with the error correction module 305 through a separate interface (not shown).

Referring back to FIG. 1, the memory device 104 may comprise a non-volatile memory which can retain data stored therein even if it is not supplied with power. The memory device 104 may further comprise a volatile memory. The memory device 104 may store data provided from the host 108 through a write operation, and the memory device 104 may also provide the stored data to the host 108 through a read operation. In examples of the present disclosure, the memory device 104 may comprise any memory as disclosed, for example, a volatile memory device such as a dynamic random access memory (DRAM) and a static RAM (SRAM), or a non-volatile memory device such as a read-only memory (ROM), a mask ROM (MROM), a programmable ROM (PROM), an erasable programmable ROM (EPROM), an electrically erasable programmable ROM (EEPROM), a ferroelectric RAM (FRAM), a phase-change RAM (PRAM), a magnetoresistive RAM (MRAM), a resistive RAM (RRAM or ReRAM) and a flash memory (e.g., a three-dimensional NAND flash).

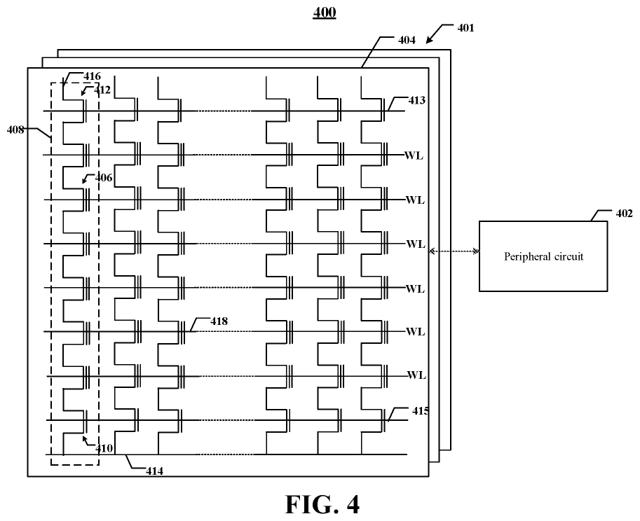

The memory device is illustrated by taking a three-dimensional NAND flash as an example. Referring to FIG. 4, FIG. 4 shows a schematic circuit diagram of an memory device 400 comprising a peripheral circuit according to some aspects of the present disclosure. The memory device 400 may be an example of the memory devices 104 in FIG. 1. The memory device 400 may comprise a memory array 401 and a peripheral circuit 402 coupled to the memory array 401. The memory array 401 is described by taking a three-dimensional NAND memory array as an example, wherein memory cells 406 are provided in an array of NAND memory strings 408, and each NAND memory string 408 extends vertically above a substrate (not shown). In some implementations, each NAND memory string 408 comprises a plurality of memory cells 406 that are coupled in series and stacked vertically. Each memory cell 406 can maintain a continuous, analog value, such as electrical voltage or charge, which depends on the number of electrons trapped within a region of the memory cell 406. Each memory cell 406 may be either a “floating gate” type memory cell that includes a floating gate transistor, or a “charge trap” type memory cell that includes a charge trap transistor.

In some implementations, each memory cell 406 is a single-level cell (SLC) having two possible memory states and therefore can store one bit of data. For example, the first memory state “0” may correspond to a first range of voltage, and the second memory state “1” may correspond to a second range of voltage. In some implementations, each memory cell 406 is a multi-level cell (MLC) that is capable of storing more than one bit of data in more than four memory states. For example, the MLC can store two bits per memory cell, three bits per memory cell (also called a trinary-level cell (TLC)), four bits per memory cell (also called a quad-level cell (QLC)), or five bites per memory cell (also called a penta-level cell (PLC)). Each MLC can be programmed to take a range of possible nominal storage values. In an example, if each MLC stores two bits of data, the MLC can be programmed to take one of three possible program levels from an erase state by writing one of three possible nominal storage values to the cell, and a fourth nominal storage value may be used for the erase state.

As shown in FIG. 4, each NAND memory string 408 may comprise a bottom select gate (BSG) 410 at its source terminal and a top select gate (TSG) 412 at its drain terminal. BSG 410 and TSG 412 may be configured to activate the selected NAND memory string 408 during the read and program operations. In some implementations, sources of the NAND memory strings 408 in the same memory block 404 are coupled through a same source line (SL) 414 (e.g., a common SL). In other words, according to some implementations, all the NAND memory strings 408 in the same memory block 404 have an array common source (ACS). According to some implementations, the TSG 412 of each NAND memory string 408 is coupled to a respective bit line (BL) 416 which the data can be read from or written into via an output bus (not shown). In some implementations, each NAND memory string 408 is configured to be selected or unselected by applying a select voltage (e.g., above a threshold voltage of a transistor having the TSG 412) or an unselect voltage (e.g., 0 V) to the respective TSG 412 via one or more TSG lines 413 and/or by applying a select voltage (e.g., above a threshold voltage of a transistor having the BSG 410) or an unselect voltage (e.g., 0 V) to the respective BSG 410 via one or more BSG lines 415.

As shown in FIG. 4, the NAND memory strings 408 can be configured into multiple memory blocks 404, each of which may have a common source line 414, e.g., coupled to the ground. In some implementations, each memory block 404 is a basic data unit for the erase operation, i.e., all of the memory cells 406 on the same memory block 404 are erased at the same time. In order to erase the memory cells 406 in a selected memory block 404, the source lines 414 coupled to the selected memory block 404 as well as unselected memory blocks 404 that are in a same plane as the selected memory block 404 can be biased with an erase voltage (Vers), such as a high positive voltage (e.g., 20 V or higher). It is to be understood that in some examples, an erase operation may be performed at a half memory block level, a quarter memory block level, or a level having any suitable number of memory blocks or any suitable fractions of a memory block. The memory cells 406 of adjacent ones of the NAND memory strings 408 may be coupled through word lines 418 that select which row of memory cells 406 is affected by the read and program operations.

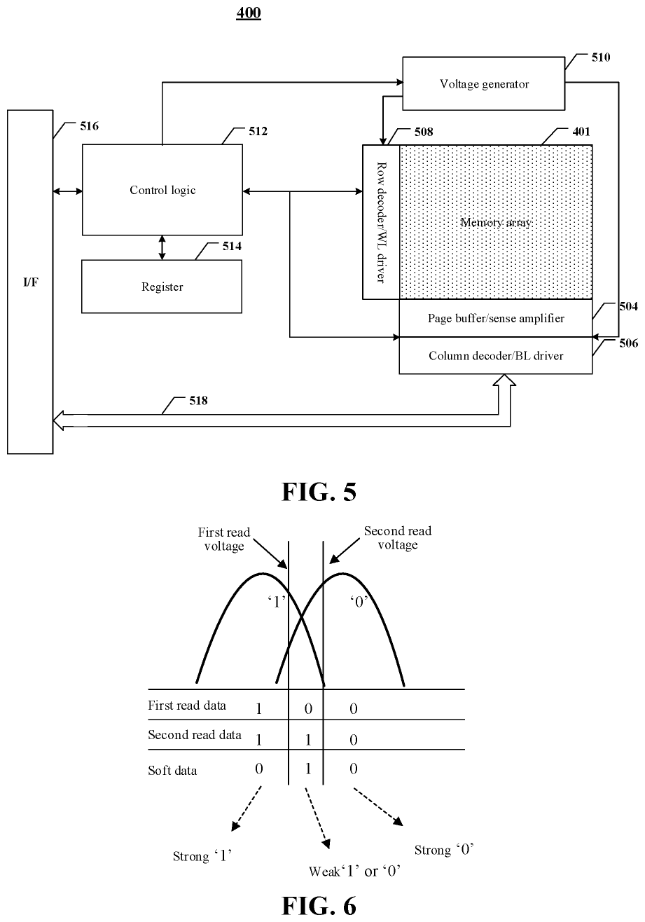

Referring back to FIG. 4, the peripheral circuit 402 may be coupled to the memory array 401 through bit lines 416, word lines 418, source lines 414, BSG lines 415 and TSG lines 413. The peripheral circuit 402 may include any suitable analog, digital, and hybrid signal circuits for facilitating the operations of the memory array 401 by applying and sensing voltage signals and/or current signals to and from each target memory cell 406 via the bit lines 416, the word lines 418, the source lines 414, the BSG lines 415, and the TSG lines 413. The peripheral circuit 402 may include various types of circuits formed using a metal-oxide-semiconductor (MOS) technology. For example, FIG. 5 shows some example peripheral circuits. The peripheral circuit 402 comprises a page buffer/sense amplifier 504, a column decoder/bit line driver 506, a row decoder/word line driver 508, a voltage generator 510, a control logic 512, a register 514, an interface 516, and a data bus 518. It is understood that in some examples, additional peripheral circuits not shown in FIG. 6 may be included as well.

The page buffer/sense amplifier 504 may be configured to read and program (write) data from and to the memory array 401 according to control signals from the control logic 512. In one example, the page buffer/sense amplifier 504 may store program data (write data) to be programmed into the memory array 401. In another example, the page buffer/sense amplifier 504 may perform programming verify operations to ensure that the data has been properly programmed into the memory cells 406 that are coupled to the selected word lines 418. In yet another example, the page buffer/sense amplifier 504 may also sense low power signals from the bit lines 416 that represent data bits stored in the memory cells 406, and amplify small voltage swings to recognizable logic levels in read operations. The column decoder/bit line driver 506 may be configured to be controlled by the control logic 512 and select one or more NAND memory strings 408 by applying bit line voltages generated from the voltage generator 510.

The row decoder/word line driver 508 may be configured to be controlled by the control logic 512 and select/unselect the memory blocks 404 of the memory array 401 and select/unselect the word lines 418 of the memory blocks 404. The row decoder/word line driver 508 may be further configured to drive the word lines 418 using word line voltages generated from the voltage generator 510. In some implementations, the row decoder/word line driver 508 may also select/unselect and drive the BSG lines 415 and the TSG lines 413. The row decoder/word line driver 508 may be configured to perform the erase operations on the memory cells 406 that are coupled to (one or more) selected word lines 418. The voltage generator 510 may be configured to be controlled by the control logic 512 and generate a word line voltage (such as, a read voltage, a program voltage, a pass voltage, a channel boost voltage, a verify voltage, etc.), a bit line voltage and a source line voltage to be supplied to the memory array 401.

The control logic 512 may be coupled to each of the peripheral circuits described above, such as the voltage generator 510, the row decoder/word line driver 508, etc., and configured to control the operations of each circuit. The register 514 may be coupled to the control logic 512 and include a state register, a command register, and an address register for storing state information, command operation codes (OP codes), and command addresses for controlling the operations of each peripheral circuit. The interface 516 may be coupled to the control logic 512, and act as a control buffer to buffer and relay control commands received from a host (not shown) to the control logic 512 and state information received from the control logic 512 to the host. The interface 516 may be also coupled to the column decoder/bit line driver 506 via a data bus 518 and act as a data I/O interface and a data buffer to buffer and relay the data to and from the memory array 401.

The memory device in the examples of the present application includes, but is not limited to, a three-dimensional NAND memory. For case of understanding, the illustration is made by taking the three-dimensional (3D) NAND memory as an example.

In the 3D NAND memory device, with the increase of the number of stored bits and the increase of the number of stack layers of the memory cell, the types of errors included are more and more complex. An adopted error correction procedure may comprise: first performing hard decoding; then performing soft decoding if the hard decoding fails; then, performing Redundant Array of Independent NAND error correction finally if the soft decoding fails. In order to take the good effect of the soft decoding, a soft read reference voltage used thereby is particularly important. Information input by the soft decoding to a next stage decoder may be a log-likelihood ratio (LLR), i.e., so-called soft data. The soft data is probability information evaluating the reliability of read data, which is used to measure the reliability of the decision. The read data here is reference read data, while a read voltage for obtaining the reference read data is the soft read reference voltage.

As shown in FIG. 6, assuming that first read data read using a first read voltage is 100; second read data read using a second read voltage is 110; and the soft data is 010 accordingly. In this case, if the first read data is regarded as the reference read data, then a bit of “0” in the soft data indicates that the reliability of this bit in the first read data is high. In other words, this bit is decided to be relatively close to reality. For example, in FIG. 6, taking the first read data as the reference read data, its left-most bit is “1”, and the number in the soft data corresponding to the bit is “0”, then the reliability of the bit is relatively high, i.e., strong “1”. By analogy, the number of the soft data corresponding to a middle bit in the first read data is “1”, then the reliability of the middle bit is weak, i.e., weak ‘1’ or ‘0’; and the right-most bit in the first read data is strong “0”. When taking the second read data as the reference read data, the analysis is similar, which is no longer repeated here.

However, many memory controllers applied in the memory system do not have a digital signal processing engine (DSP) and cannot obtain an optimal soft read reference voltage by complex computation through its hardware; and the data read predominantly relies on a firmware (FW) algorithm to recover data in the memory device to keep a storage medium in the memory device in a relatively good state, so as to read the data correctly through the hard decoding before the soft decoding; or relies on subsequent RAID error correction to rebuild the data. The industry cannot solve the UECC problems in some harsh application scenarios before rebuild. This will lead to enter a rebuild procedure in harsh scenarios, resulting in a dramatic decline of read performance.

In order to search the above optimal soft read reference voltage, in some examples, the DSP engine is added in the memory controller of the memory system, and the optimal soft read reference voltage is obtained by algorithm computation. In some other examples, the memory device of the memory system may employ a memory chip having an optimal read voltage searching function, i.e., the memory device itself searches the optimal soft read reference voltage. Furthermore, one or more fixed read voltages are given as the soft read reference voltage of the soft decoding, and a read voltage in a harsh scenario that is not covered by the FW algorithm may be selected as the soft read reference voltage.

In order to search the above-mentioned optimal soft read reference voltage, examples of the present application provide an operation method of a memory system, which obtains at least one first read voltage as a soft read reference voltage for subsequent soft decoding through a preset mapping relationship that is established in advance.

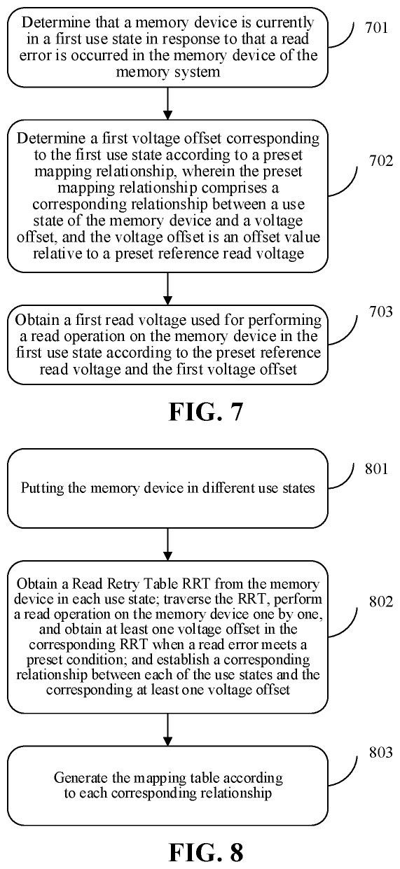

In an example, referring to FIG. 7, FIG. 7 is a flow diagram of an operation method of a memory system provided by examples of the present application.

In an example, the operation method may comprise:
operation 701: determining that a memory device is currently in a first use state in response to that a read error is occurred in the memory device of the memory system;
operation 702: determining a first voltage offset corresponding to the first use state according to a preset mapping relationship, wherein the preset mapping relationship comprises a corresponding relationship between a use state of the memory device and a voltage offset, and the voltage offset is an offset value relative to a preset reference read voltage; and
operation 703: obtaining a first read voltage used for performing a read operation on the memory device in the first use state according to the preset reference read voltage and the first voltage offset.

It is to be noted that, actually, an error correction procedure is only initiated when a read operation is performed on the memory device and the read data has an error. Then, the operation method of the examples of the present application should also be triggered only when the memory device is read and the read data has an error, that is, in response to that a read error is occurred in the memory device, it is determined that the memory device is currently in the first use state. Then, the first voltage offset is obtained according to the preset mapping relationship and the first use state, and then the first read voltage is obtained, wherein the first voltage offset may include one or more first voltage offsets; accordingly, the first read voltage may also include one or more first read voltages; in other words, one first voltage offset corresponds to one first read voltage. Then, at least one first read voltage is selected as a subsequent soft read reference voltage for subsequent soft decoding.

The operation method provided by the examples of the present application is used to obtain the first read voltage and then obtain the soft read reference voltage. Its advantages lie in that the memory controller in the memory system is not required to have a DSP engine, etc., such that additional cost caused by use of a special memory controller is reduced, more types of memory controllers can be adapted, and the time required to obtain the soft read reference voltage is short; a storage medium (such as a NAND medium) in the memory device is also not required to have a function of automatically searching an optimal read voltage, more storage media can be adapted, and the time required to obtain the soft read reference voltage is also short; and the examples of the present application establish the preset mapping relationship according to the use state corresponding to the memory device and can better match practical application scenarios.

Implementation of the operation method provided by the examples of the present application is introduced in detail below.

Referring back to the procedure in FIG. 1, occurring of a read error in the memory device may refer to that an error is occurred in the read data during data reading from the memory device. When the memory device has the read error, the memory controller in the memory system may perform error correction decoding (such as using the aforementioned error correction (ECC) module 305 in FIG. 3 for error correction decoding) to correct the error occurring in the read data. A use scenario of the operation method provided by the examples of the present application includes, but is not limited to, a use scenario where performing the soft decoding when the memory device has the read error is to perform selection of the soft read reference voltage. For example, the use scenario of the examples of the present application may further include selection of the read voltage in a normal read operation, and selection of the read voltage in hard decoding, etc.

Here, the use state of the memory device may refer to a use state of the storage medium (e.g., the NAND medium) that it comprises; in an example, it may refer to the use state of the storage medium that the memory device comprises when it is at a code word (CW) to be decoded currently (which may be the soft read data in the soft decoding or an inverted code word to be decoded in an iteration) in the soft decoding procedure.

The use state may be evaluated by using state parameters such as an erase count (EC), a program to read time, a read count, a program/read temperature, etc. of the storage medium in the memory device, which will be illustrated in detail subsequently.

Here, the preset mapping relationship may refer to a corresponding relationship between the use state of the memory device and the voltage offset established through a large number of experiments or experience records. The voltage offset may refer to an offset value relative to the preset reference read voltage, wherein the preset reference read voltage may refer to a reference voltage in the Read Retry Table (RRT). The preset mapping relationship provided by the examples of the present application includes, but is not limited to, a mapping table.

It is to be noted that, the RRT is a table including a plurality of voltage offsets, wherein each voltage offset is relative to the preset reference read voltage. These voltage offsets are achieved by a hardware circuit in the memory device. For example, a register that the memory device comprises may store one or more of the above voltage offsets; and the memory controller may change values of the voltage offsets by configuring these registers in the memory device.

In other words, a process of applying the read voltage in a read operation may comprise: the memory device determines the voltage offset to be applied in response to a read command; then, the voltage offset required is obtained from the register of the memory device; then, the voltage offset is transferred to a voltage generator which obtains the required read voltage by superposition of the voltage offset and the preset reference read voltage (including superposition of signs, i.e., if the voltage offset is negative, the final read voltage is smaller than the preset reference read voltage), which is, in turn, applied to a respective word line.

That is to say, the respective preset reference read voltage is stored in the voltage generator, and the voltage offset is transferred between the memory controller and the memory device. Finally, the voltage offset is superposed on the preset reference read voltage value in the voltage generator, so as to apply the required read voltage to the respective word line.

For the RRT, for example, as shown in Table 1, it is an RRT corresponding to a TLC type of memory cell provided by the examples of the present application.

Each column in Table 1 represents a set of voltage offsets for distinguishing adjacent program states from the corresponding preset reference read voltages, i.e., Rd1 to Rd7.

It is to be noted that, since the TLC type of memory cell has 8 data states, it can be distinguished by 7 read voltages, i.e., Table 1 has 7 columns.

The set of voltage offsets described above may include positive offsets increasing towards a direction greater than the preset reference read voltage, and negative offsets decreasing towards a direction less than the preset reference read voltage.

For example, for Rd7, +V1, +V2, +V3 and +V4 are positive offsets, wherein numerical values of V1, V2, V3 and V4 increase sequentially; while −V5 to −V11 are negative offsets, wherein numerical values of V5 to V11 decrease sequentially.

TABLE 1
RRT

| Rd1 | Rd2 | Rd3 | Rd4 | Rd5 | Rd6 | Rd7 |
|---|---|---|---|---|---|---|
| — | — | — | — | — | — | 0 |
| — | — | — | — | — | — | +V1 |
| — | — | — | — | — | — | +V2 |
| — | — | — | — | — | — | +V3 |
| — | — | — | — | — | — | +V4 |
| — | — | — | — | — | — | −V5 |
| — | — | — | — | — | — | −V6 |
| — | — | — | — | — | — | −V7 |
| — | — | — | — | — | — | −V8 |
| — | — | — | — | — | — | −V9 |
| — | — | — | — | — | — | −V10 |
| — | — | — | — | — | — | −V11 |

According to the aforementioned RRT and the definition of the preset mapping relationship, obtaining of the preset mapping relationship may be referred to FIG. 8; the preset mapping relationship may comprise the mapping table; and the method may further comprise:
operation 801: putting the memory device in different use states;
operation 802: obtaining a Read Retry Table (RRT) from the memory device in each use state; traversing the RRT, performing a read operation on the memory device one by one, and obtaining at least one voltage offset in the corresponding RRT when a read error meets a preset condition; and establishing a corresponding relationship between each of the use states and the corresponding at least one voltage offset; and
operation 803: generating the mapping table according to each corresponding relationship.

It is to be noted that, the putting the memory device in different use states may refer to processing (such as read, erase and write processing) the memory device during experiments in order to establish the preset mapping relationship, and putting the memory device in different use states according to different state parameters of the memory device during read, erase and write.

In some examples, the state parameters comprise at least one of: the erase count, the program count, the read count, the read temperature, the program temperature and the program to read time interval of the memory device; and operation 801 may comprise:
assigning values to the erase count, the program count, the read count, the read temperature, the program temperature and the program to read time interval to form multiple sets of state parameters; and
processing the memory device according to the multiple sets of state parameters to put the memory device in different use states,
wherein each set of state parameters corresponds to one use state of the memory device.

It is to be noted that, as described above, the use state of the memory device may be represented by the erase count, the program count, the read count, the read temperature, the program temperature and the program to read time interval as described herein; and then, different state parameter combinations may represent that the memory device is in different use states. Therefore, first, values may be assigned to the erase count, the program count, the read count, the read temperature, the program temperature and the program to read time interval to form multiple sets of state parameters, i.e., representing the use states of the memory device corresponding to the state parameters. It should be understood that, putting the memory device in different use states does not mean that the state parameters are simply configured to the memory device, but the memory device is processed (e.g., read, write, erase, and other processing), such that the state parameter of the memory device reaches the assigned state parameter.

In other words, first, values are assigned to the state parameters (at least one of the erase count, the program count, the read count, the read temperature, the program temperature and the program to read time interval) to form multiple sets of state parameters; each set of state parameters corresponds to one use state of the memory device; then, the memory device is processed, such as the above-mentioned read, write, erase and other processing, such that the memory device reaches one of the multiple sets of state parameters, which represents that the memory device reaches the use state corresponding to the set of state parameters. Thereafter, the memory device is processed sequentially to make the memory device reach the multiple sets of state parameters sequentially, thereby ensuring that the memory device reaches each use state.

In a practical application process, the higher assigned value of each parameter of the state parameters represents a harsher application scenario corresponding to the use state. In a harsher application scenario, more read errors occur when the memory device performs the read operation. Moreover, it is to be understood that, the use state of the memory device is worsened gradually. Therefore, processing the memory device to put the memory device in different use states is also performed sequentially according to such a principle.

When the memory device is in each use state, the RRT is obtained from the memory device; then the RRT is traversed, the read operation is performed on the memory device once by one, and at least one voltage offset in the corresponding RRT when the read error meets a preset condition is obtained; and then a corresponding relationship between each use state and the corresponding at least one voltage offset is established, wherein all the corresponding relationship constitute the mapping table. That is, the mapping table contains each of the aforementioned corresponding relationships. The mapping table may be stored in the memory controller or the memory device, which depends on a size of the mapping table.

Here, the RRT may be stored in the storage medium of the memory device. When the RRT is in use, the memory controller needs to read the RRT from the memory device. The traversing the RRT and performing the read operation on the memory device one by one is to perform the read operation on the memory device according to the read voltage formed by superposition of each voltage offset in the RRT table and the preset reference read voltage.

It is to be understood that, the TLC type of memory cell as shown in Table 1 corresponds to totally 7 sets of voltage offsets, Rd1 to Rd7, wherein each set obtains at least one voltage offset with the read error meeting the preset condition. After each set obtains the at least one voltage offset, the corresponding relationship is established with the corresponding use state, and this corresponding relationship is one in the mapping table.

Here, the read error meeting the preset condition may refer to that the read error is not greater than a certain threshold, or there are fewest read errors. For example, under a certain voltage offset, when the number of read errors occurring in the memory device is not greater than a certain threshold or the number of the read errors occurring is the fewest, the voltage offset has the read error meeting the preset condition. In a practical application process, the number of error bits included in the read data may be evaluated by using a syndrome weight value; and the higher the syndrome weight value is, the larger the number of the error bits included in the read data is. Therefore, in the examples of the present application, if the read error meets the preset condition, it may also use the syndrome weight value corresponding to the read data obtained when reading the memory device at some voltage offset being minimum or being less than a certain threshold to determine whether the voltage offset is the voltage offset with the read error meeting the preset condition.

It is to be particularly noted that, even in the case of fewest read errors, there may be a plurality of obtained voltage offsets meeting the preset condition. Therefore, there may be the voltage offset making the memory device have fewest read errors in the RRT. The threshold described above may be set by a designer, for example, the threshold may be a numerical value, such as 1, 2, 3, etc.

For example, the mapping table is as shown in Table 2.

In the mapping table as shown in Table 2, the RRT is a voltage offset table corresponding to the TLC type of memory cell as shown in Table 1. A NAND state is a specific example of the storage medium of the memory device described above. Moreover, the program count, the read count, the program temperature/read temperature and the program to read time are used to characterize the use state of the NAND; and RR-1, RR-2, RR-3, . . . , and RR-n are at least one voltage offset corresponding to the use state as described above.

It is to be noted that, one use state corresponding to one voltage offset as described in Table 2 is only an example. In a practical use process, as described above, one use state may correspond to at least one voltage offset.

TABLE 2
Mapping Table

| RRT | | | | | | | | | | | | |
|---|---|---|---|---|---|---|---|---|---|---|---|---|
| Options | | | | | | | | NAND state | | | | |
| (at least | | | | | | | | | | Program | | |
| one | | | | | | | | | | temperature/ | Program | |
| voltage | | | | | | | | Program | Read | read | to read | |
| offset) | Rd1 | Rd2 | Rd3 | Rd4 | Rd5 | Rd6 | Rd7 | count | count | temperature | time | . . . |
| RR-1 | — | — | — | — | — | — | — | — | — | — | — | — |
| RR-2 | — | — | — | — | — | — | — | — | — | — | — | — |
| RR-3 | — | — | — | — | — | — | — | — | — | — | — | — |
| . . . | . . . | . . . | . . . | . . . | . . . | . . . | . . . | . . . | . . . | . . . | . . . | . . . |
| RR-n | | | | | | | | | | | | |

After obtaining the aforementioned mapping table, in some examples, the method may further comprise:
updating the erase count, the program count, the read count, the read temperature, the program temperature and the program to read time interval regularly; and
the determining that the memory device is currently in the first use state comprises:
looking up the erase count, the program count, the read count, the read temperature, the program temperature and the program to read time interval updated latest as the first use state.

An operation of obtaining the first use state of the memory device is described here. The memory device updates values recording and characterizing the state parameters at a certain time interval, that is, records a new use state of the memory device. Then, the state parameter recorded latest is looked up to determine the first use state of the memory device.

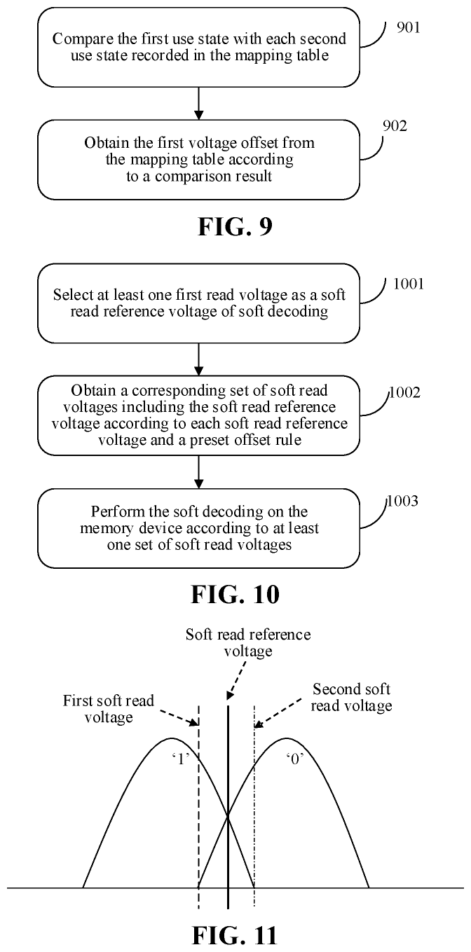

After obtaining the mapping table and the first use state, in some examples, as shown in FIG. 9, operation 703 may comprise:
operation 901: comparing the first use state with each second use state recorded in the mapping table; and
operation 902: obtaining the first voltage offset from the mapping table according to a comparison result.

In some examples, the state parameters include a plurality of state parameters; and the operation 901 may comprise:
comparing each parameter of the state parameters in the first use state with each parameter of the state parameters in each second use state correspondingly; and
the operation 902 may comprise:
determining a second voltage offset corresponding to the second use state from the mapping table as the first voltage offset, if the comparison result comprises that a ratio of the state parameters of the first use state and a certain second use state having the same parameter exceeds a first set threshold value; or
determining a second voltage offset corresponding to the second use state from the mapping table as the first voltage offset, if the comparison result comprises that an absolute value of a difference in corresponding parameters in the state parameters of the first use state and a certain second use state does not exceed a second set threshold value; or
determining a second voltage offset corresponding to the second use state from the mapping table as the first voltage offset, if the comparison result comprises that a ratio of the state parameters of the first use state and a certain second use state having the same parameter exceeds the first set threshold value and an absolute value of a difference in corresponding parameters in the state parameters of the first use state and the second use state does not exceed the second set threshold value.

It is to be noted that, the state parameters may comprise at least one of the erase count, the program count, the read count, the read temperature, the program temperature and the program to read time interval of the memory device as described before. When the state parameters include a plurality of state parameters, each parameter of the state parameters corresponding to the first use state is correspondingly compared with each parameter of the state parameters in each second use state recorded in the mapping table; that is, the erase count of the first use state is compared with the erase count of each second use state; and the program count of the first use state is compared with the program count of each second use state, and so on. Here, the use state of the memory device recorded in the mapping table is recorded as the second use state so as to distinguish from the current first use state of the memory device. It should be understood that the terms first and second here are not limitations on the number, but are different descriptions for distinguishing in different scenarios.

Afterwards, the first voltage offset is obtained from the mapping table according to the comparison result; in an example, a second voltage offset corresponding to the second use state is determined as the first voltage offset, if the comparison result comprises that a ratio of the state parameters of the first use state and a certain second use state having the same parameter exceeds a first set threshold value; or a second voltage offset corresponding to the second use state is determined as the first voltage offset, if the comparison result comprises that an absolute value of a difference in corresponding parameters in the state parameters of the first use state and a certain second use state does not exceed a second set threshold value; or a second voltage offset corresponding to the second use state is determined from the mapping table as the first voltage offset, if the comparison result comprises that a ratio of the state parameters of the first use state and a certain second use state having the same parameter exceeds the first set threshold value and an absolute value of a difference in corresponding parameters in the state parameters of the first use state and the second use state does not exceed the second set threshold value.

Here, the ratio of the state parameters of the first use state and a certain second use state having the same parameter exceeding the first set threshold value may refer to that a ratio of the number of values of a plurality of parameters included in the state parameters in the first use state being the same as values of a plurality of parameters included in the state parameters in a certain second use state to the number of the plurality of parameters included in the state parameters exceeds the first preset threshold value.

For example, assuming that the state parameters include a total of 6 parameters, i.e., the erase count, the program count, the read count, the read temperature, the program temperature and the program to read time interval of the memory device, and assuming that the first preset threshold value is ⅔, that is, the values of 4 or more of the parameters included in the state parameters in the first use state are the same as the parameter values of the state parameters in the second use state, and the second voltage offset corresponding to the second use state is determined as the first offset voltage corresponding to the first use state at this time.

In another case, the absolute value of the difference in the corresponding parameters in the state parameters of the first use state and a certain second use state not exceeding the second set threshold value may refer to that an absolute value of a difference between a value of each parameter in the first use state and a value of a corresponding parameter in a certain second use state does not exceed the second preset threshold value.

For example, assuming that the state parameters include a total of 6 parameters, i.e., the erase count, the program count, the read count, the read temperature, the program temperature and the program to read time interval of the memory device, and assuming that the first preset threshold value is 1, that is, an absolute value of a difference between the erase count in the first use state and the erase count in a certain second use state cannot exceed 1, an absolute value of a difference between the program counts cannot exceed 1, an absolute value of a difference between the read counts cannot exceed 1, an absolute value of a difference between the read temperatures cannot exceed 1 degree, an absolute value of a difference between the program temperatures cannot exceed 1 degree, and an absolute value of a difference between the program to read time intervals cannot exceed 1 (second, or microsecond, or nanosecond, or other suitable time units).

In another case, the ratio of the state parameters of the first use state and a certain second use state having the same parameter exceeding the first set threshold value and the absolute value of the difference in the corresponding parameters in the state parameters of the first use state and the second use state not exceeding the second set threshold value may refer to that the second voltage offset corresponding to the second use state is determined as the first voltage offset when the ratio of the same parameters in the state parameters in a certain second use state and the first use state included in the mapping table exceeds the first preset threshold value and the absolute value of the difference between the corresponding parameters of various parameters does not exceed the second set threshold value.

It is to be noted that, regardless of which case, the second voltage offset may include one or more voltage offsets.

After obtaining the first voltage offset, operation 703 may comprise: performing operation on the preset reference read voltage with each first voltage offset to obtain at least one first read voltage in the first use state.

It is to be noted that, as shown in Table 1 above, the operation here is a signed operation. In other words, the first read voltage obtained may be greater than the preset reference read voltage, or may be less than the preset reference read voltage, or may be even equal to the preset reference read voltage. This totally depends on whether the first voltage offset is positive or negative. When the first voltage offset is 0, the first read voltage is even equal to the preset reference read voltage.

After obtaining one or more first read voltages, in some examples, as shown in FIG. 10, the method may further comprise:
operation 1001: selecting at least one first read voltage as a soft read reference voltage of soft decoding;
operation 1002: obtaining a corresponding set of soft read voltages including the soft read reference voltage according to each soft read reference voltage and a preset offset rule; and
operation 1003: performing the soft decoding on the memory device according to at least one set of soft read voltages.

It is to be noted that, after obtaining one or more first read voltages by the aforementioned methods, during the soft decoding, at least one first read voltage may be selected as the soft read reference voltage of the soft decoding (i.e., operation 1001) for one or more times of soft decoding. After obtaining one or more soft read reference voltages, a corresponding set of soft read voltages including the reference read voltage is obtained according to each soft read reference voltage and the preset offset rule (i.e., operation 1002); and then, the soft decoding is performed on the memory device according to at least one set of soft read voltages (operation 1003) to obtain correct read data.

Here, the preset offset rule in operation 1002 may refer to offsetting according to a predetermined offset interval by taking the soft read reference voltage as a center to obtain a plurality of soft read voltages. For example, as shown in FIG. 11, the read voltage in the middle position is the soft read reference voltage; the read voltage at the right and the left thereof are read voltages set according to the preset offset rule; and the set of soft read voltages may refer to voltages including the soft read reference voltage and the read voltages on two sides thereof. It is to be noted that, here only taking the soft read reference voltage as the center, a set of read voltages is formed by offsetting to the right and left each by a certain amount. In a practical application process, a set of soft read voltages may include more voltages, which may be set according to the specific cases, which is not described in detail here.

In some examples, operation 1003 may comprise:
performing the soft decoding on the memory device gradually according to one set of soft read voltages of a plurality of sets of soft read voltages; and finishing the soft decoding on the memory device until the soft decoding passes and/or the number of times of performing the soft decoding reaches a preset threshold value.

It is to be noted that, in a practical application process, a plurality of sets of soft read voltages obtained may be all used to perform the soft decoding on the memory device, or only one or more sets of soft read voltages may be used, such that the correct read data can be obtained. That is to say, when performing the soft decoding on the memory device based on a plurality of sets of soft read voltages, the soft decoding is performed on the memory device gradually according to a set of soft read voltages of the plurality of sets of soft read voltages; and the soft decoding on the memory device is finished until the soft decoding passes and/or the number of times of performing the soft decoding reaches a preset threshold value. The preset threshold value may be set artificially, and its numerical value may be the same as the number of sets of the plurality of sets of soft read data. That is, when the soft decoding is performed on the memory device, in the case where the soft decoding passes and/or the number of times of performing the soft decoding reaches a preset threshold value, the soft decoding is finished, such that correct read data is output, or it enters a next stage of error correction. When the soft decoding passes and the number of times of performing the soft decoding reaches the preset threshold value, the correct read data may be also output, and the whole error correction procedure is finished.

Each soft decoding procedure is similar, with an exception of the difference in the soft read reference voltage and the reference read data. In the description below, a description is made according to a soft decoding to illustrate the soft decoding procedure. That is, performing the soft decoding on the memory device according to the set of soft read voltages may comprise:
obtaining a set of voltage offsets corresponding to the set of soft read voltages;
configuring the set of voltage offsets to the memory device to make the memory device obtain the set of soft read voltages according to the set of voltage offsets and the preset reference read voltage, and obtain a set of soft read data according to the set of soft read voltages; and
performing soft decoding on the set of soft read data.

It is to be noted that, according to the above description of the RRT table, when the read operation is performed on the memory device, the memory device determines the voltage offset to be applied in response to a read command; then, the voltage offset required is obtained from the register of the memory device; then, the voltage offset is transferred to a voltage generator which obtains the required read voltage by superposition of the voltage offset and the preset reference read voltage (including superposition of signs, i.e., if the voltage offset is negative, the final read voltage is smaller than the preset reference read voltage), which is, in turn, applied to a respective word line. That is, in the examples of the present application, the memory controller will obtain a corresponding set of voltage offsets according to the set of soft read voltages determined above, then configures the set of voltage offsets to the memory device, and the configuration here means that the set of voltage offsets is written to a corresponding register in the memory device; then, the memory controller sends a read command to the memory device, and the memory device applies a respective read voltage to a respective word line to obtain a set of soft read data according to the above-mentioned procedure of applying the read voltage to the word line and the obtained set of voltage offsets in response to the read command. Then, the soft decoding is performed according this set of soft read data. The specific soft decoding process is not illustrated in detail here.

In some examples, the method may further comprise:
determining a set of hard read voltages according to the preset reference read voltage and a Read Retry Table (RRT) before determining that the memory device is currently in the first use state, wherein the set of hard read voltages comprises a default read voltage and a plurality of re-read voltages, and the plurality of re-read voltages have a certain offset from the preset reference read voltage; and
performing hard decoding on the memory device according to the set of hard read voltages.

It is to be noted that, what is described here is hard decoding as a stage prior to soft decoding. In an example, a set of hard read voltages is determined according to the preset reference read voltage and the Read Retry Table (RRT), and may include a default read voltage and a plurality of re-read voltages with a certain offset from the preset reference read voltage. Here, the default voltage value may refer to a first voltage value for the read operation during the hard decoding, wherein the default read voltage may be preset in the memory system according to experience. The default read voltage may be the same as or different from the preset reference read voltage in the Retry Read Table (RRT). The plurality of re-read voltages may be a set of read voltages formed by the RRT and the default read voltage according to a certain offset setting. A specific offset setting may be set by those skilled in the art. Afterwards, at least one time of hard decoding is performed according to the set of hard read voltages. Moreover, the error correction is finished in one of the following cases: the hard decoding passes and/or the number of times of hard read retry reaches a maximum set number of times.

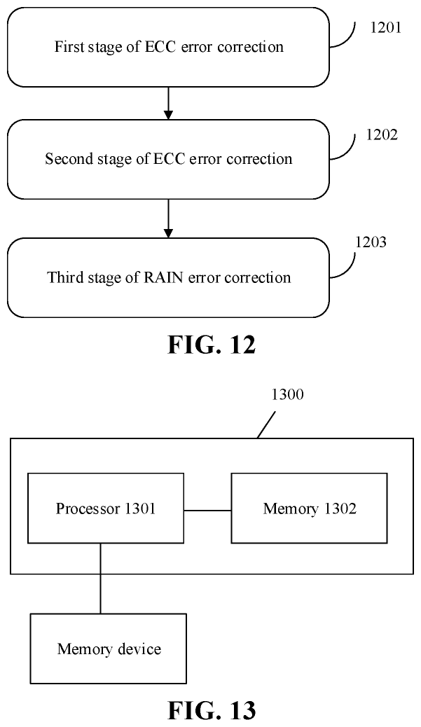

According to the above description, referring to FIG. 12, examples of the present application provide an error correction procedure of a memory system. The error correction procedure may comprise:

Operation 1201: a first stage of ECC error correction, i.e., hard decoding.

The first stage of ECC error correction comprises: initial reading; hard decoding of initial read data; performing first-time re-read and hard decoding when the initial reading fails, and so on, and performing next decoding when a decoding fails. The first stage of ECC error correction is finished in at least one of the following cases: the number of times of re-read reaches a threshold, or the hard decoding passes.

Operation 1202: a second stage of ECC error correction, i.e., soft decoding.

The second stage of ECC error correction comprises: at least one time of soft decoding. Moreover, the soft read reference voltage used for each soft decoding may be obtained by the methods described above.

Operation 1203: a third stage of RAIN error correction, i.e., Redundant Array of Independent NAND (RAIN) error correction.

After the third stage of RAIN error correction fails, indication information for characterizing error correction failure is output; and when the third stage of RAIN error correction passes, a read data corrected successfully is output.

According to the operation method of the memory system provided by the examples of the present application, the soft read reference voltage in the soft decoding can be obtained simply, quickly and accurately through the established mapping table between the use state of the memory device and the voltage offset required for read, such that the error correction time of soft decoding is reduced, and the probability that the soft decoding passes is increased. Moreover, according to the operation method provided by the examples of the present application, the memory controller is not required to have a module such as a DSP and the like for complex operation to obtain the respective soft read reference voltage, and the storage medium of the memory device is also not required to have a function of searching an optimal read voltage. By clearly recording the use state of the memory device at a current CW and adequately characterizing the storage medium of the memory device, one or more pre-stored voltage offsets in the RRT corresponding to the current CW can be mapped accurately so as to obtain the reference read voltage of subsequent soft decoding, increase the probability that the soft decoding passes, and avoid entering a subsequent rebuild procedure to affect a read performance of the memory device. The operation method may be adapted to more controllers and improve the read performance (read time required by operation of the memory controller) at the same time; the operation method may be also adapted to more storage media (such as a NAND medium) and improve the read performance (time required by a function of the NAND itself to search); and the operation method may also reduce the probability of UECC in a harsh application scenario, increase the probability that the soft decoding passes, reduces the probability of entering the subsequent rebuild procedure and improves the read performance in an extreme scenario.

Based on the same inventive concept, examples of the present application further provide a memory controller. As shown in FIG. 13, the memory controller 1300 is coupled with one or more memory devices 1303, and the memory controller comprises a processor 1301, wherein
the processor 1301 is configured to: determine that the memory device 1303 is in a first use state in response to that a read error is occurred in the memory device; determine a first voltage offset corresponding to the first use state according to a preset mapping relationship; and obtain a first read voltage used for performing a read operation on the memory device in the first use state according to the preset reference read voltage and the first voltage offset, wherein the preset mapping relationship includes a corresponding relationship between a use state of the memory device and a voltage offset, and the voltage offset is an offset value relative to a preset reference read voltage.

It is to be noted that a structure of the memory controller here is predominantly the same as that of the memory controller as shown in FIG. 3 above. Various components of the memory controller provided by the examples of the present application also implement the operation method provided by the examples of the present application in addition to the functions as illustrated and described in FIG. 3 above. The operation method is mainly implemented in the processor 1301 in the memory controller.

In some examples, the preset mapping relationship is stored in the memory device; the memory controller further comprises a memory 1302; and
the processor is further configured to: send a first read command to the memory device; receive the preset mapping relationship fed back by the memory device in response to the first read command; and buffer the preset mapping relationship to the memory.

In some examples, the first voltage offset includes one or more first voltage offsets; the first read voltage includes one or more first read voltages; and the processor is further configured to: select at least one first read voltage as a soft read reference voltage of soft decoding; obtain a corresponding set of soft read voltages including the soft read reference voltage according to each soft read reference voltage and a preset offset rule; and perform the soft decoding on the memory device according to at least one set of soft read voltages.

In some examples, the preset mapping relationship comprises a mapping table; the memory controller further comprises a memory 1302; and
the processor is further configured to: send a second read command to the memory device; receive a Read Retry Table (RRT) fed back by the memory device in response to the second read command, and buffer the RRT to the memory; put the memory device in different use states; in each use state, traverse the RRT in the memory, perform a read operation on the memory device one by one, and obtain at least one voltage offset in the corresponding RRT when a read error meets a preset condition; establish a corresponding relationship between each of the use states and the corresponding at least one voltage offset; and generate the mapping table according to each corresponding relationship.

In some examples, the state parameters comprise at least one of: an erase count, a program count, a read count, a read temperature, a program temperature and a program to read time interval of the memory device; and the processor is further configured to: assign values to the erase count, the program count, the read count, the read temperature, the program temperature and the program to read time interval to form multiple sets of state parameters; and process the memory device according to the multiple sets of state parameters to put the memory device in different use states, wherein each set of state parameters corresponds to one use state of the memory device.

In some examples, the processor is further configured to: compare the first use state with each second use state recorded in the mapping table; and obtain the first voltage offset from the mapping table according to the comparison result.

In some examples, the processor is further configured to: compare each parameter of the state parameters in the first use state with each parameter of the state parameters in each second use state correspondingly,
wherein a second voltage offset corresponding to the second use state is determined from the mapping table as the first voltage offset, if the comparison result comprises that a ratio of the state parameters of the first use state and a certain second use state having the same parameter exceeds a first set threshold value; or a second voltage offset corresponding to the second use state is determined from the mapping table as the first voltage offset, if the comparison result comprises that an absolute value of a difference in corresponding parameters in the state parameters of the first use state and a certain second use state does not exceed a second set threshold value; or a second voltage offset corresponding to the second use state is determined from the mapping table as the first voltage offset, if the comparison result comprises that a ratio of the state parameters of the first use state and a certain second use state having the same parameter exceeds the first set threshold value and an absolute value of a difference in corresponding parameters in the state parameters of the first use state and the second use state does not exceed the second set threshold value.

In some examples, the processor is further configured to: update the erase count, the program count, the read count, the read temperature, the program temperature and the program to read time interval in the memory regularly; and look up the erase count, the program count, the read count, the read temperature, the program temperature and the program to read time interval updated latest from the memory as the first use state.

It is to be noted that, the memory controller provided by the examples of the present application is configured to implement the operation method provided by the examples of the present application. Specific implementation of the operation method has been described above in detail, which is no longer repeated here.

Based on the same inventive concept, examples of the present application further provide a memory system, which may comprise:
one or more memory devices; and
a memory controller coupled with the one or more memory devices and configured to control the one or more memory devices, wherein
the memory controller comprises a processor configured to: determine that the memory device is in a first use state in response to that a read error is occurred in the memory device; determine a first voltage offset corresponding to the first use state according to a preset mapping relationship; and obtain a first read voltage used for performing a read operation on the memory device in the first use state according to the preset reference read voltage and the first voltage offset,
wherein the preset mapping relationship includes a corresponding relationship between a use state of the memory device and a voltage offset, and the voltage offset is an offset value relative to a preset reference read voltage.

In some examples, the memory device comprises: a memory array and a peripheral circuit coupled with the memory array, wherein
the peripheral circuit comprises a control logic and a register, wherein
the processor is further configured to: obtain a set of voltage offsets corresponding to one set of soft read voltages of a plurality of sets of soft read voltages; and configure each voltage offset of the set of voltage offsets to the register;
the control logic is configured to: access the register to obtain the set of voltage offsets;
obtain the set of soft read voltages according to a preset reference read voltage and the set of voltage offsets; and gradually provide each soft read voltage of the set of soft read voltages to selected word lines corresponding to selected memory cells included in the memory array to obtain a corresponding set of soft read data; and
the processor is further configured to: perform soft decoding on the set of soft read data.

It is to be noted that, a structure of the memory system provided here and structures of the memory controller and the memory device which the memory system comprises are predominantly the same as those in FIGS. 1 to 6 above. The memory system provided by the examples of the present application is further configured to implement the operation method provided by the examples of the present application.

In an example, in the processor included in the memory controller in the memory system, the soft read reference voltage of the soft decoding is obtained according to the operation procedure described above, and then a set of soft read voltages is obtained according to the soft read reference voltage and the preset offset rule to further perform the soft decoding. During performing the soft decoding, the processor included in the memory controller obtains a set of voltage offsets corresponding to a set of a plurality of sets of soft read voltages, and configure each voltage offset in the set of voltage offsets into a corresponding register; afterwards, the control logic included in the peripheral circuit accesses the register and obtains the set of voltage offsets, obtains the set of soft read voltages according to the preset reference read voltage and the set of voltage offsets, gradually provides each soft read voltage of the set of soft read voltages to a selected word line corresponding to a selected memory cell included in the memory array to obtain a respective set of soft read data, and the set of soft read data is fed back to the processor; and the processor performs the soft decoding on the set of soft read data. How to perform the soft decoding is not described in detail here.

The above descriptions are intended to be illustrative, and not restrictive. For example, the above-mentioned instances (or one or more aspects thereof) may be used in combination with each other. Other examples may be used, such as those that can be used by those of ordinary skill in the art upon reading the above description. It should be understood that it will not be used to explain or limit the scope or meaning of the claims. In addition, in the above detailed description, various features may be combined together to simplify the present application. This should not be construed to mean that the disclosed features that are not claimed are necessary for any claim. Instead, the subject matter of the disclosure may be less than all features of a particular disclosed example. Thus, the appended claims are hereby incorporated into the detailed description, with each claim standing on its own as a separate example, and it is expected that these examples can be combined with each other in various combinations or replacements. The scope of the present application should be determined with reference to the appended claims, along with the full scope of equivalents to which such claims are entitled.

What is claimed is:

1. An operation method of a memory system, comprising:
determining that a memory device of the memory system is currently in a first use state in response to determining that a read error is occurred in the memory device;
determining a first voltage offset corresponding to the first use state according to a preset mapping relationship, wherein the preset mapping relationship comprises a corresponding relationship between a use state of the memory device and a voltage offset, and the voltage offset comprises an offset value relative to a preset reference read voltage; and
obtaining at least one first read voltage for performing a read operation on the memory device in the first use state according to the preset reference read voltage and the first voltage offset.

2. The operation method of claim 1, wherein the first voltage offset comprises one or more first voltage offset values, and the at least one first read voltage comprises one or more first read voltages, and
wherein the operation method further comprises:
selecting at least one of the one or more first read voltages as a soft read reference voltage of soft decoding;
for each soft read reference voltage, obtaining a corresponding set of soft read voltages including the soft read reference voltage according to the soft read reference voltage and a preset offset rule; and
performing the soft decoding on the memory device according to at least one set of soft read voltages.

3. The operation method of claim 1, wherein the preset mapping relationship comprises a mapping table, and wherein the operation method further comprises:
putting the memory device in different use states;
obtaining a Read Retry Table (RRT) from the memory device in each use state; traversing the RRT, performing a read operation on the memory device one by one, and obtaining at least one voltage offset in the corresponding RRT when a read error meets a preset condition; and establishing a corresponding relationship between each of the use states and the corresponding at least one voltage offset; and
generating the mapping table according to each corresponding relationship.

4. The operation method of claim 3, wherein state parameters comprise at least one of: an erase count, a program count, a read count, a read temperature, a program temperature, and a program to read time interval of the memory device, and
wherein the putting the memory device in the different use states comprises:
assigning values to the erase count, the program count, the read count, the read temperature, the program temperature and the program to read time interval to form multiple sets of state parameters; and
processing the memory device according to the multiple sets of state parameters to put the memory device in the different use states,
wherein each set of state parameters corresponds to a respective use state of the memory device.

5. The operation method of claim 3, wherein the determining the first voltage offset corresponding to the first use state according to the preset mapping relationship comprises:
comparing the first use state with each second use state recorded in the mapping table; and
obtaining the first voltage offset from the mapping table according to a comparison result.

6. The operation method of claim 5, wherein the state parameters include a plurality of state parameters,
wherein the comparing the first use state with the second use state recorded in the mapping table comprises:
comparing each parameter of the state parameters in the first use state with each parameter of the state parameters in each second use state correspondingly, and
wherein the obtaining the first voltage offset from the mapping table according to the comparison result comprises at least one of:
determining a second voltage offset corresponding to the second use state from the mapping table as the first voltage offset, if the comparison result comprises that a ratio of the state parameters of the first use state and a certain second use state having the same parameter exceeds a first set threshold value;
determining a second voltage offset corresponding to the second use state from the mapping table as the first voltage offset, if the comparison result comprises that an absolute value of a difference in corresponding parameters in the state parameters of the first use state and a certain second use state does not exceed a second set threshold value; or
determining a second voltage offset corresponding to the second use state from the mapping table as the first voltage offset, if the comparison result comprises that a ratio of the state parameters of the first use state and a certain second use state having the same parameter exceeds the first set threshold value and an absolute value of a difference in corresponding parameters in the state parameters of the first use state and the second use state does not exceed the second set threshold value.

7. The operation method of claim 4, further comprising:
updating the erase count, the program count, the read count, the read temperature, the program temperature and the program to read time interval regularly,
wherein the determining that the memory device is currently in the first use state comprises:
looking up the erase count, the program count, the read count, the read temperature, the program temperature and the program to read time interval updated latest as the first use state.

8. The operation method of claim 2, further comprising:
determining a set of hard read voltages according to the preset reference read voltage and a Read Retry Table (RRT) before determining that the memory device is currently in the first use state, wherein the set of hard read voltages comprises a default read voltage and a plurality of re-read voltages, and the plurality of re-read voltages have a predetermined offset from the preset reference read voltage; and
performing hard decoding on the memory device according to the set of hard read voltages.

9. The operation method of claim 2, wherein the performing the soft decoding on the memory device according to at least one set of soft read voltages comprises:
performing the soft decoding on the memory device gradually according to one set of soft read voltages of a plurality of sets of soft read voltages; and
finishing the soft decoding on the memory device until at least one of
the soft decoding passes or
the number of times of performing the soft decoding reaches a preset threshold value.

10. The operation method of claim 9, wherein the performing the soft decoding on the memory device according to one set of soft read voltages comprises:
obtaining a set of voltage offsets corresponding to the set of soft read voltages;
configuring the set of voltage offsets to the memory device to make the memory device obtain the set of soft read voltages according to the set of voltage offsets and the preset reference read voltage, and obtain a set of soft read data according to the set of soft read voltages; and
performing the soft decoding on the set of soft read data.

11. A memory controller coupled with one or more memory devices, comprising:
at least one processor; and
at least one memory storing programming instructions for executions by the at least one processor to perform operations comprising:
in response to determining that a read error is occurred in a memory device, determining that the memory device is in a first use state;
determining a first voltage offset corresponding to the first use state according to a preset mapping relationship; and
obtaining at least one first read voltage used for performing a read operation on the memory device in the first use state according to the preset reference read voltage and the first voltage offset, wherein the preset mapping relationship includes a corresponding relationship between a use state of the memory device and a voltage offset, and the voltage offset comprises an offset value relative to a preset reference read voltage.

12. The memory controller of claim 11, wherein the preset mapping relationship is stored in the memory device,
wherein the operations further comprise:
sending a first read command to the memory device;
receiving the preset mapping relationship fed back by the memory device in response to the first read command; and
buffering the preset mapping relationship to the at least one memory.

13. The memory controller of claim 11, wherein the first voltage offset comprises one or more first voltage offset values, and the at least one first read voltage comprises one or more first read voltages, and
wherein the operations further comprise:
selecting at least one of the one or more first read voltages as a soft read reference voltage of soft decoding;
for each soft read reference voltage, obtaining a corresponding set of soft read voltages including the soft read reference voltage according to the soft read reference voltage and a preset offset rule; and
performing the soft decoding on the memory device according to at least one set of soft read voltages.

14. The memory controller of claim 11, wherein the preset mapping relationship comprises a mapping table, and
wherein the operations further comprise:
sending a second read command to the memory device;
receiving a Read Retry Table (RRT) fed back by the memory device in response to the second read command, and buffering the RRT to the at least one memory;
putting the memory device in different use states;
in each use state, traversing the RRT in the memory, performing a read operation on the memory device one by one, and obtaining at least one voltage offset in the corresponding RRT when a read error meets a preset condition;
establishing a corresponding relationship between each of the use states and the corresponding at least one voltage offset; and
generating the mapping table according to each corresponding relationship.

15. The memory controller of claim 14, wherein state parameters comprise at least one of: an erase count, a program count, a read count, a read temperature, a program temperature and a program to read time interval of the memory device; and
wherein the operations further comprise:
assigning values to the erase count, the program count, the read count, the read temperature, the program temperature and the program to read time interval to form multiple sets of state parameters; and
processing the memory device according to the multiple sets of state parameters to put the memory device in different use states, wherein each set of state parameters corresponds to one use state of the memory device.

16. The memory controller of claim 14, wherein the operations further comprise:
comparing the first use state with each second use state recorded in the mapping table; and
obtaining the first voltage offset from the mapping table according to a comparison result.

17. The memory controller of claim 16, wherein the operations further comprise:
comparing each parameter of the state parameters in the first use state with each parameter of the state parameters in each second use state correspondingly,
wherein a second voltage offset corresponding to the second use state is determined from the mapping table as the first voltage offset, if the comparison result comprises that a ratio of the state parameters of the first use state and a certain second use state having the same parameter exceeds a first set threshold value; or a second voltage offset corresponding to the second use state is determined from the mapping table as the first voltage offset, if the comparison result comprises that an absolute value of a difference in corresponding parameters in the state parameters of the first use state and a certain second use state does not exceed a second set threshold value; or a second voltage offset corresponding to the second use state is determined from the mapping table as the first voltage offset, if the comparison result comprises that a ratio of the state parameters of the first use state and a certain second use state having the same parameter exceeds the first set threshold value and an absolute value of a difference in corresponding parameters in the state parameters of the first use state and the second use state does not exceed the second set threshold value.

18. The memory controller of claim 15, wherein the processor is further configured to: update the erase count, the program count, the read count, the read temperature, the program temperature and the program to read time interval in the memory regularly; and look up the erase count, the program count, the read count, the read temperature, the program temperature and the program to read time interval updated latest from the memory as the first use state.

19. A memory system, comprising:
one or more memory devices; and
a memory controller coupled with the one or more memory devices and configured to control the one or more memory devices, wherein
the memory controller is configured to:
determine that a memory device is in a first use state in response to determining that a read error is occurred in the memory device;
determine a first voltage offset corresponding to the first use state according to a preset mapping relationship; and
obtain at least one first read voltage for performing a read operation on the memory device in the first use state according to the preset reference read voltage and the first voltage offset,
wherein the preset mapping relationship includes a corresponding relationship between a use state of the memory device and a voltage offset, and the voltage offset comprises an offset value relative to a preset reference read voltage.

20. The memory system of claim 19, wherein the memory device comprises: a memory array and a peripheral circuit coupled with the memory array, and wherein the peripheral circuit comprises a control logic and a register,
wherein the memory device is further configured to: obtain a set of voltage offsets corresponding to a set of soft read voltages of a plurality of sets of soft read voltages, and configure each voltage offset of the set of voltage offsets to the register,
wherein the control logic is configured to: access the register to obtain the set of voltage offsets, obtain the set of soft read voltages according to a preset reference read voltage and the set of voltage offsets, and gradually provide each soft read voltage of the set of soft read voltages to selected word lines corresponding to selected memory cells included in the memory array to obtain a corresponding set of soft read data, and
wherein the memory device is further configured to: perform soft decoding on the set of soft read data.
